(19) United States
(12) Patent Application Publication
(10) Pub. No.: US 2008/0311753 A1
(43) Pub. Date: Dec. 18, 2008

(54) OXYGEN SACVD TO FORM SACRIFICAL OXIDE LINERS IN SUBSTRATE GAPS

(75) Inventors: Yi Zheng, San Jose, CA (US); Sasha J. Kweskin, San Francisco, CA (US); Kedar Sapre, Mountain View, CA (US); Nitin K. Ingle, Santa Clara, CA (US); Zheng Yuan, Fremont, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/136,931

(22) Filed: Jun. 11, 2008

Related U.S. Application Data
(60) Provisional application No. 60/944,303, filed on Jun. 15, 2007.

(51) Int. Cl. H01L 21/311

(52) U.S. Cl. 438/694; 216/11; 257/E21.249

(57) ABSTRACT

A method of forming and removing a sacrificial oxide layer is described. The method includes forming a step on a substrate, where the step has a top and sidewalls. The method may also include forming the sacrificial oxide layer around the step by chemical vapor deposition of molecular oxygen and TEOS, where the oxide layer is formed on the top and sidewalls of the step. The method may also include removing a top portion of the oxide layer and the step; removing a portion of the substrate exposed by the removal of the step to form a etched substrate; and removing the entire sacrificial oxide layer from the etched substrate.

### CROSS-REFERENCES TO RELATED APPLICATIONS

The present application claims benefit under 35 USC 119(e) of U.S. provisional Application No. 60/944,303, filed on Jun. 15, 2007 entitled “Oxygen SACVD To Form Sacrifical Oxide Liners In Substrate Gaps,” the content of which is incorporated herein by reference in its entirety.

### BACKGROUND OF THE INVENTION

As the device density and functionality of semiconductor integrated circuit chips continue to increase, new solutions are needed to form these devices at ever smaller scales. Conventional photolithography has been used successfully to form device patterns down to 65 nm scales. However, as the scales are reduced even further (e.g., sub-45 nm scales) challenges arise from physical limits on the resolution of optical lithography.

The resolution of a lithography system may be described by the Rayleigh Equation [R=k₁(λ/NA)], where k₁ is a proportionality constant that has a limiting value of 0.25 for a single exposure, λ is the wavelength of light used, and NA is the numerical aperture of the optics used. Each of these variables influence the optical resolution of photolithographic patterning techniques. For example, by increasing NA, decreasing the wavelength λ, and/or decreasing k₁, the resolution will be improved and photolithographic patterning can achieve smaller scales. However, there are many challenges to adjusting each of the variables to improve the resolution.

For example, increasing the value of the numerical aperture NA will require new high index immersion fluids and optical materials. However, the development of new materials with the required optical properties and a higher refractive index has proved challenging.

Decreasing the wavelength λ, is also encountering technical challenges as lower (i.e., deeper) UV wavelengths accessible by conventional excimer laser technology are being tested. While the 248 nm line has been implemented successfully for 100 nm scaling, and the 193 nm line has shown success for scaling to 65 nm and some 45 nm devices, moving to lower excimer wavelengths as been difficult. Attempts to develop photolithography for the 157 nm excimer line, for example, has so far not been successful. The challenges include limited availability of optical material (i.e., crystalline CaF₂ optics) and lack of immersion fluids with sufficiently high transmission and index of refraction. Moreover, even if these challenges can be met, the decrease in wavelength from 193 nm to 157 nm was not large enough to significantly improve the resolution of the photolithography done at 157 nm.

Development is also underway for extreme ultra-violet systems (EUV) that can generate wavelengths of light 10 to 15 times shorter than current 193 nm technology (e.g., 13.5 nm). These systems will require replacing immersion fluids and conventional optics with vacuum and fully reflective optics because most materials will absorb these short wavelengths. At present, development of these EUV systems has just started, and the development of new mask, source, and resist infrastructure is expected to take several years.

Another possibility to increase the resolution is to lower the k₁ value of the Rayleigh Equation through a double patterning process. One double patterning technique, known as lithographic double patterning, involves splitting a chip pattern having a k₁ value at or below 0.25 into to two or more separate mask patterns that have k₁ values greater than 0.25. The first mask pattern may be exposed and etched into a hardmask film before a photoresist coats the patterned hardmask. The second mask is aligned with the etched pattern before the photoresist is exposed and etched. The dual patterning an etching allows device structures to be formed on the surface with a scaling that is smaller than the resolution limit defined by the Rayleigh Equation.

While lithographic double patterning holds the promise of extending the current infrastructure for 193 nm photolithography to smaller scales, it also introduces significant technical challenges. These include the difficulty in achieving pattern to pattern overlay between the mask patterns at the precision needed. There are also some efficiency losses incurred by the increased number of photoresist deposition, patterning, and etching steps needed for patterning with multiple masks. Thus, there is a need for additional techniques to decrease device scale and increase device density in the fabrication of integrated circuit chips.

### BRIEF SUMMARY OF THE INVENTION

Embodiments of the invention include methods of forming and removing a sacrificial oxide layer is described. The methods may include forming a step on a substrate, where the step has a top and sidewalls. The methods may also include forming the sacrificial oxide layer around the step by chemical vapor deposition of molecular oxygen and TEOS, where the oxide layer is formed on the top and sidewalls of the step. The methods may also include removing a top portion of the oxide layer and the step; removing a portion of the substrate exposed by the removal of the step to form a etched substrate; and removing the entire sacrificial oxide layer from the etched substrate.

Embodiments of the invention further include methods to incorporate a sacrificial oxide layer in a photolithography process. The methods may include forming a first and second photoresist layer on a substrate, and patterning the second photoresist layer to form a step that has a top and sidewalls. The methods may further include forming the sacrificial oxide layer around the step by chemical vapor deposition of molecular oxygen and TEOS, where the oxide layer is formed on the top and sidewalls of the step. Additional steps may include removing a top portion of the oxide layer and the step; removing a portion of the first photoresist layer exposed by the removal of the step; and removing a portion of the underlying substrate exposed by the removal of the portion of the first photoresist layer to form an etched gap in the substrate. The methods may still also include removing the entire sacrificial oxide layer from the etched substrate.

Embodiments of the invention also include methods to incorporate a sacrificial oxide layer in a semiconductor gap formation process. The methods may include the steps of forming a photoresist layer on a substrate, and patterning the photoresist layer to form a step structure. The methods may still further include forming the sacrificial oxide layer around the step structure by chemical vapor deposition of molecular oxygen and TEOS. The methods may further include removing a top portion of the oxide layer to form unconnected first and second oxide structures on opposite sidewalls of the step structure; removing the step structure between the oxide structures; and removing a portion of the underlying substrate that is not covered by the oxide structures to form an etched gap in the substrate. The oxide structures may be removed from the etched substrate.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a drawing showing relationships between deposition rates and pressures according to exemplary methods of the invention;

FIG. 2 is a drawing showing Fourier Transform Infrared Spectroscopy (FTIR) curves of dielectric films formed by the methods according to embodiments of the invention; and

FIGS. 3A-3G are schematic cross-sectional views showing an exemplary double patterning method according to an embodiment of the invention.

### DETAILED DESCRIPTION OF THE INVENTION

Depositions of sacrificial films of silicon oxide using SACVD are described. The deposition processes include exposing a deposition substrate to a mixture of silicon precursor (e.g., TEOS) and molecular oxygen at high total pressures (e.g., about 100 Torr or more) and moderate temperatures (e.g., about 300° C. to about 500° C.) to form a conformal film on the substrate surface. The use of molecular oxygen instead of ozone as the oxygen precursor improves the compatibility of the oxide deposition with carbon-containing resist materials, such as the Advanced Patterning Film (APF) made by Applied Materials of Santa Clara, Calif.

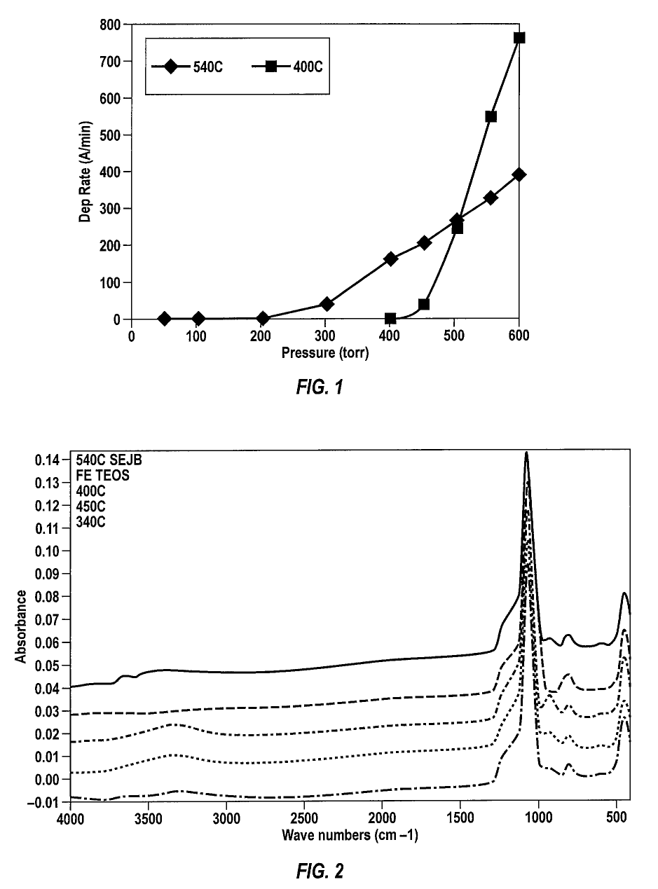

Sacrificial oxide films with good conformality and quality can be formed by SACVD using TEOS and O₂ at moderate temperatures (e.g., <600° C. or 400° C.-450° C.). While conventional SACVD with TEOS and O₂ has been used to form oxide films at deposition temperatures higher than 600° C., films formed at lower temperatures often suffered from unpredictable conformity and quality. It has been discovered that TEOS and O₂ run at pressures of about 100 Torr or more (e.g., 500 Torr) can deposit an oxide film with good conformity and quality at deposition temperatures less than about 600° C. The films may have a thickness of about 100 Å to about 600 Å at a deposition rate of about 100 Å/min to about 600 Å/min (e.g., about 550 Å/min). The deposited film has excellent conformality in high aspect ratio gaps, and a WERR that is suitable for the efficient etching and removal of a sacrificial oxide layer. FIG. 1 is a drawing showing relationships between deposition rates and pressures according to exemplary methods of the invention. As shown in FIG. 1, the deposition rate curve representing the processing temperature of about 540° C. smoothly inclines from the pressure of about 200 Torr, and the deposition rate curve representing the processing temperature of about 400° C. can rapidly increase from the pressure of about 400 Torr. Accordingly, a desired deposition rate and/or conformity of the sacrificial film can be formed at the temperature of about 600° C. or less over the topography of the substrate.

FIG. 2 is a drawing showing Fourier Transform Infrared Spectroscopy (FTIR) curves of dielectric films formed by methods according to embodiments of the invention. As shown in FIG. 2, the peaks of the FTIR curves appear around the wavenumber of about 1100 (cm-1). The peaks represent silicon-oxygen bonds of the dielectric films and indicate that the dielectric films are oxide films.

Among other applications, these films may be used as sacrificial spacer structures in spacer dual patterning photolithographic techniques. In spacer dual patterning, the sacrificial oxide forms a conformal film around patterned photoresist structures. The film is then partially etched to “open” those portions covering the tops of the photoresist structures. The photoresist material is then removed to leave sacrificial oxide structures that define a pattern on the underlying substrate. Portions of the substrate that are not covered by the oxide may then be etched to form a pattern of gaps in the substrate. The sacrificial oxide may then be removed from the etched substrate. An illustration of an exemplary spacer dual patterning technique, using a Sub-atmospheric Oxide Litho Optimizer (SOLO) deposition of a sacrificial oxide, is illustrated in the accompanying figures. The SOLO deposition is called an ACE deposition.

Because the sacrificial oxide film can be deposited with O₂ instead of ozone (O₃), the deposition process is compatible with underlying layers and structures made from carbon-containing materials. These may include amorphous carbon films such as the Advanced Patterning Film (APF), whose uses in double patterning schemes is described in U.S. Pat. No. 6,924,191 to Liu et al, titled “METHOD FOR FABRICATING A GATE STRUCTURE OF A FIELD EFFECT TRANSISTOR”; and U.S. Pat. No. 7,064,078 to Liu et al., titled “TECHNIQUES FOR THE USE OF AMORPHOUS CARBON (APF) FOR VARIOUS ETCH AND LITHO INTEGRATION SCHEME”, of which the entire contents of both patents are herein incorporated by reference for all purposes. In addition, dual patterning techniques that involve low-temperature ozone deposition processes are described in a U.S. Provisional patent application by Chandrasekaran et al, filed the same day as the present application, and titled “LOW TEMPERATURE SACVD PROCESSES FOR PATTERN LOADING APPLICATIONS” the entire contents of which is herein incorporated by reference for all purposes.

### Exemplary Deposition Process

Exemplary deposition processes include Sub-Atmospheric Chemical Vapor Deposition (SACVD) processes, Atmospheric Pressure Chemical Vapor Deposition (APCVD) processes, or other CVD processes. The deposition processes may include introducing an silicon-containing precursor (e.g., silane, an organo-silane or organo-siloxane precursor such as tetraethylorthosilicate (TEOS), trimethylsilane, tetramethylsilane, dimethylsilane, diethylsilane, tetramethylcyclotetrasiloxane, etc.) and molecular oxygen (O₂) into a deposition chamber and chemically reacting them to deposit a sacrificial silicon oxide film on a deposition substrate.

The SACVD processes may also include introducing an inert gas and/or carrier gas to the deposition chamber. Carrier gases carry the silicon precursor and/or oxygen to the deposition chamber, and inert gases help maintain the chamber at a particular pressure. Both types of gases may include helium, argon, and/or nitrogen (N₂), among other kinds of gases.

The flow rates for the reactive precursors and carrier/inert gases may be controlled to provide the appropriate partial pressures of gases in the deposition chamber. For example, in a deposition that uses TEOS as the silicon-containing precursor with molecular oxygen, the TEOS may flow at a rate of about 4000 mgm, the molecular oxygen may flow at about 30 slm, helium may flow at 15 slm, nitrogen may flow at about 5 slm, and additional nitrogen (N₂) from, for example, an RPS may flow at a rate of about 500 slm. The deposition substrate may be spaced about 250 to about 325 mil from a showerhead faceplate where the precursors enter the deposition chamber.

The combination of the inert/carrier gases and the deposition precursors (e.g., TEOS and O₂) may be used to set the pressure of the deposition chamber to a range of about 100 Torr to about 760 Torr. Exemplary pressures include about 300 Torr, 400 Torr, 500 Torr, 600 Torr, etc.

As noted above, sacrificial oxide depositions using TEOS and molecular oxygen may be conducted at moderate temperatures (e.g., about 300° C. to about 500° C.; about 400° C. to about 450° C.; etc.). Examples include depositing the sacrificial oxide film at a temperature from about 400° C. to about 450° C. until the film reaches a thickness of about 100 Å to about 600 Å. The pressure, temperature and precursor flow conditions may be adjusted such that the film is deposited at a rate from about 1 Å/min to about 600 Å/min (e.g., about 100 Å/min to about 600 Å/min; about 550 Å/min, etc.). In embodiments, H₂O can be added to the reactive precursors to desirably increase the deposition rate of the sacrificial oxide film and/or desirably expand the process window to even lower temperature. For example, the deposition rate of the sacrificial oxide film can be doubled (e.g., about 1,200 Å/min). Additional details of SACVD dielectric depositions (and in particular SACVD depositions) are described in U.S. Pat. No. 6,905,940 to Ingle et al, titled “METHOD USING TEOS RAMP-UP DURING TEOS/OZONE CVD FOR IMPROVED GAPFILL,” the entire contents of which are herein incorporated by reference for all purposes.

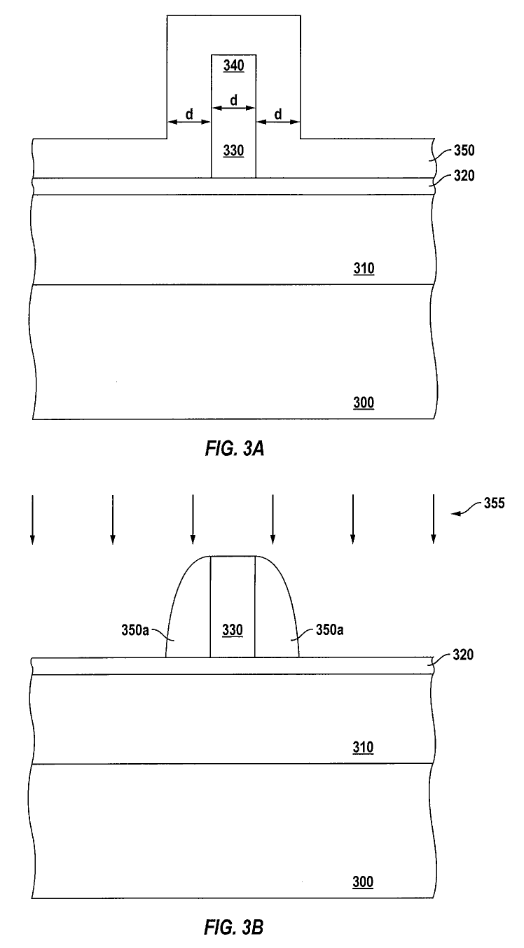

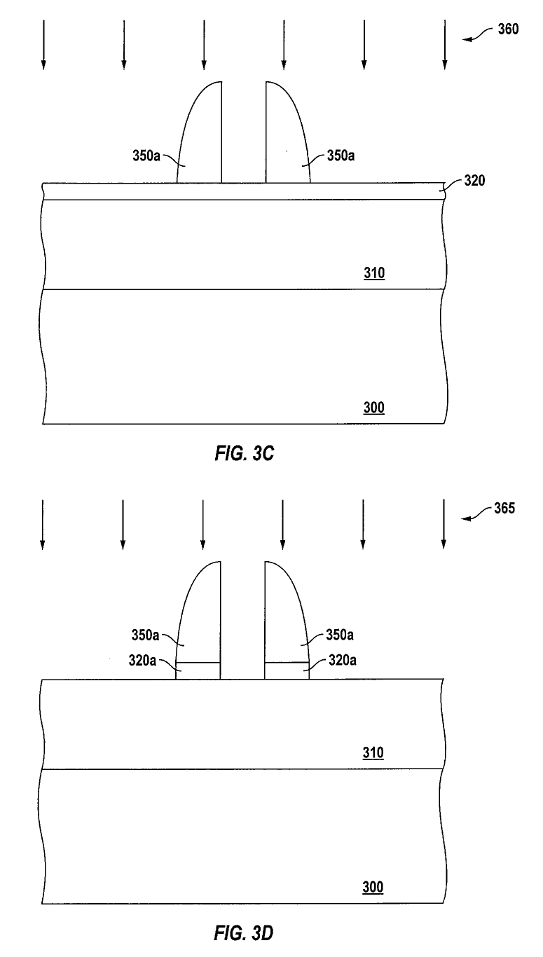

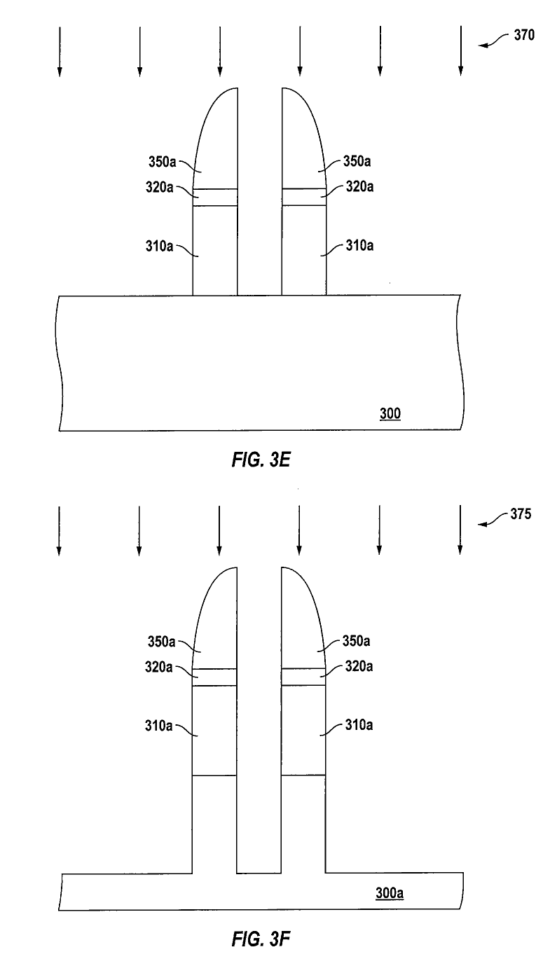

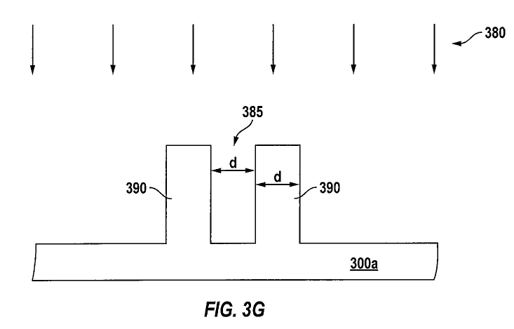

FIGS. 3A-3G are schematic cross-sectional views showing an exemplary double patterning method according to an embodiment of the invention. In FIG. 3A, Advanced Patterning Film (APF) 310, e.g., an amorphous carbon-containing layer, is formed over substrate 300. Etch-stop layer 320, e.g., a nitride layer, oxynitride layer or other dielectric layer, can be formed over APF 310. Patterned APF 330 and cap layer 340, such as a nitride layer, are formed over etch-stop layer 320. In embodiments, patterned APF 330 and cap layer 340 can be formed by patterning an APF layer and a cap layer by using a photolithographic process and an etching process. Sacrificial layer 350 can be formed substantially conformal over patterned APF 330 and cap layer 340. Sacrificial layer 350 can be formed by, for example, SOLO deposition processes or ACE deposition processes. In embodiments, APF 330 can have a width “d” and sacrificial layer 350 can have a thickness “d” on the sidewalls of APF 330. In embodiments, the width “d” can be about 32 nm or less.

In FIG. 3B, etching process 355 can remove a portion of sacrificial layer 350 and cap layer 340 (shown in FIG. 3A) to form sacrificial spacers 350a on sidewalls of APF 330 and expose the top of APF 330. Etch-stop layer 320 can protect APF 310 from damage caused by etching process 355. The portion of sacrificial layer 350 and cap layer 340 can be removed by a single process or multiple processes.

In FIG. 3C, etching process 360 substantially removes APF 330 (shown in FIG. 3B) and is substantially free from damaging sacrificial spacers 350a and etch-stop layer 320. Etching process 360 can be any dry and/or wet processes that can desirably remove APF 330. In embodiments, etching process 360 can be referred to as an APF etching process.

In FIG. 3D, etching process 365 can remove a portion of etch-stop layer 320 (shown in FIG. 3C) by using sacrificial spacers 350a as a hard mask, exposing a portion of a surface of APF 310 and remaining etch-stop layers 320a. Etching process 365 can be any dry and/or wet etching processes that can desirably remove the portion of etch-stop layer 320 without substantially damaging APF 310.

In FIG. 3E, etching process 370 can remove a portion of APF layer 310 (shown in FIG. 3D) by using sacrificial spacers 350a as a hard mask, exposing a portion of a surface of substrate 300 and remaining APF layers 310a. Etching process 370 can be any dry and/or wet etch processes that can desirably remove the portion of APF layer 310. In FIG. 3F, etching process 370 can remove a portion of substrate 300 (shown in FIG. 3E) to a predetermined depth by using sacrificial spacers 350a as a hard mask. Etching process 375 can be any dry and/or wet etch processes that can desirably remove the portion of substrate 300.

In FIG. 3G, etching process 380 can substantially remove sacrificial spacers 350a, etch-stop layers 320a, and APF layers 310a. Etching process 380 can be a single or multiple removing steps for removing sacrificial spacers 350a, etch-stop layers 320a, and APF layers 310a. Referring again to FIG. 3A, APF 330 and sacrificial layer 350 on the sidewalls of APF 330 have a width “d.” The width “d” is substantially converted to the width of trench 385 and lines 390 as shown in FIG. 3G. If the width of trench 385 is, for example, about 32 nm or less, the exemplary method described in FIGS. 3A-3G can be used to form narrow trench 385, instead of using conventional photolithographic and etching processes to form the narrow patterns. The issues raised by conventional photolithographic and etching processes to form narrow patterns can be desirably avoided.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

As used herein and in the appended claims, the singular forms “a”, “and”, and “the” include plural referents unless the context clearly dictates otherwise. Thus, for example, reference to “a process” may includes a plurality of such processes and reference to “the layer” may include reference to one or more layers and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups.

What is claimed is:

1. A method of forming and removing a sacrificial oxide layer, the method comprising:
forming a step on a substrate, wherein the step has a top and sidewalls;
forming the sacrificial oxide layer around the step by chemical vapor deposition of molecular oxygen and a silicon-containing precursor, wherein the oxide layer is formed on the top and sidewalls of the step;
removing a top portion of the oxide layer and the step, while leaving a remaining portion of the oxide layer that includes at least a portion of the sidewalls;
removing a portion of the substrate exposed by the removal of the step to form an etched substrate; and
removing the remaining portion of the oxide layer from the etched substrate.

2. The method of claim 1, wherein the step comprises a photoresist material.

3. The method of claim 2, wherein the photoresist material comprises a carbon containing compound.

4. The method of claim 2, wherein the photoresist comprises an amorphous carbon film.

5. The method of claim 1, wherein the silicon-containing precursor comprises an organo-silane or organo-siloxane compound.

6. The method of claim 1, wherein the silicon-containing precursor comprises TEOS.

7. The method of claim 1, wherein the substrate wafer is heated to a temperature of about 600° C. or less during the formation of the sacrificial oxide layer.

8. The method of claim 1, wherein a total pressure in the deposition chamber is at about 100 Torr or more during the formation of the sacrificial oxide layer.

9. The method of claim 1, wherein the sacrificial oxide layer has a thickness of about 200 Å to about 600 Å when deposited.

10. The method of claim 1, wherein the sacrificial oxide layer is deposited at a rate of about 200 Å/min to about 800 Å/min.

11. The method of claim 1, wherein the silicon-containing precursor has a flow rate of about 4000 mgm and the molecular oxygen has a flow rate of about 30 slm during the formation of the sacrificial oxide layer.

12. The method of claim 1, wherein the sacrificial oxide layer is removed by a dry chemical etch using a fluorine etchant.

13. The method of claim 1, wherein the formation of the sacrificial oxide layer is done in the absence of ozone.

14. A method to incorporate a sacrificial oxide layer in a photolithography process, the method comprising:
forming a first and second photoresist layer on a substrate;
patterning the second photoresist layer to form a step that has a top and sidewalls;
forming the sacrificial oxide layer around the step by chemical vapor deposition of molecular oxygen and TEOS, wherein the oxide layer is formed on the top and sidewalls of the step;
removing a top portion of the oxide layer and the step, while leaving a remaining portion of the oxide layer;
removing a portion of the first photoresist layer exposed by the removal of the step;
removing a portion of the underlying substrate exposed by the removal of the portion of the first photoresist layer to form an etched gap in the substrate; and
removing the remaining portion of the oxide layer from the etched substrate.

15. The method of claim 14, wherein the first and second photoresist layers comprise carbon.

16. The method of claim 14, wherein the first and second photoresist layers comprise an advanced patterning film;

17. The method of claim 14, wherein the gap etched into the substrate has a width of about 40 nm or less.

18. The method of claim 14, wherein the gap etched into the substrate has a width of about 32 nm or less.

19. The method of claim 14, wherein the gap etched into the substrate has a width between about 40 nm and about 22 nm.

20. The method of claim 14, wherein a total pressure is at least 500 Torr during the deposition of the sacrificial oxide layer.

21. The method of claim 14, wherein the substrate wafer is heated to a temperature of about 400° C. to about 450° C. during the deposition of the sacrificial oxide layer.

22. The method of claim 14, wherein the sacrificial oxide layer has a thickness of about 200 Å to about 600 Å when deposited.

23. The method of claim 14, wherein the sacrificial oxide layer is deposited at a rate of about 200 Å/min to about 400 Å/min.

24. The method of claim 14, wherein the formation of the sacrificial oxide layer is done in the absence of ozone.

25. The method of claim 14, wherein the method further comprises:
forming a etch stop layer between the first and second photoresist layers and parallel to the underlying substrate, wherein a portion of the sacrificial oxide layer is formed on the etch stop layer;
removing a portion of the etch stop layer that is not protected by the overlying sacrificial oxide layer; and
removing a portion of the first photoresist layer exposed by the removal of the etch stop layer.

26. The method of claim 25, wherein the etch stop layer comprises silicon nitride.

27. A method to incorporate a sacrificial oxide layer in a semiconductor gap formation process, the method comprising:
forming a photoresist layer on a substrate;
patterning the photoresist layer to form a step structure;
forming the sacrificial oxide layer around the step structure by chemical vapor deposition of molecular oxygen and TEOS;
removing a top portion of the oxide layer to form unconnected first and second oxide structures on opposite sidewalls of the step structure;
removing the step structure between the oxide structures;
removing a portion of the underlying substrate that is not covered by the oxide structures to form an etched gap in the substrate; and
removing the oxide structures from the etched substrate.

28. The method of claim 27, wherein the etched gap has a width between about 40 nm and 20 nm.

29. The method of claim 27, wherein a total pressure is at least 500 Torr during the deposition of the sacrificial oxide layer.
